(19) United States
(12) Patent Application Publication
(10) Pub. No.: US 2025/0390650 A1
(43) Pub. Date: Dec. 25, 2025

(54) SIMULATION CLONING FOR DIGITAL TWINS

(71) Applicant: UT-Battelle, LLC, Oak Ridge, TN (US)

(72) Inventors: Srikanth B. Yoginath, Knoxville, TN (US); Sudip K. Seal, Knoxville, TN (US); James J. Nutaro, Oak Ridge, TN (US); Pratishtha Shukla, Knoxville, TN (US)

(73) Assignee: UT-Battelle, LLC, Oak Ridge, TN (US)

(21) Appl. No.: 19/215,984

(22) Filed: May 22, 2025

Related U.S. Application Data
(60) Provisional application No. 63/661,776, filed on Jun. 19, 2024.

(51) Int. Cl. G06F 30/32

(52) U.S. Cl. CPC G06F 30/32

(57) ABSTRACT

A digital twin system generates a parent [symbol] -tree simulation from a parent node by executing what-if scenarios through circuitry having a finite memory. The circuitry applies an election criterion based on the operating state of a physical twin that selects a child node from the parent [symbol] -tree simulation as a root node. The circuitry rebases the parent [symbol] -tree simulation at the root node, spawns descendants, and stores the rebase [symbol] -tree simulation in a memory. The circuitry deletes selected what-if scenarios associated with the parent [symbol] -tree simulation that lie outside of the rebase [symbol] -tree simulation memory space, and reclaims the memory storing the what-if-scenarios. The digital twin communicates with the physical twin so that the physical twin may respond to one or more intervening events before they occur in real-time.

### 2. PRIORITY CLAIM

This application claims the benefit of priority from U.S. Provisional Application No. 63/661,776, filed Jun. 19, 2024 titled “Simulation Cloning for Digital Twins”, which is incorporated herein by reference in its entirety.

### 1. STATEMENT REGARDING FEDERALLY SPONSORED RESEARCH AND DEVELOPMENT

These inventions were made with United States government support under Contract No. DE-AC05-00OR22725 awarded by the United States Department of Energy. The United States government has certain rights in the inventions.

### 3. CROSS REFERENCE TO RELATED APPLICATION

The following co-pending and commonly assigned United States patent application was filed on the same day as the present application. The following application and the provisional patent to which it claims priority to relate to and describes further embodiments and aspects of embodiments disclosed in this application and both of which are herein incorporated in their entirety by reference.

U.S. patent application Ser. No. 19/215,784, “Speculative Evaluation of What-if Scenarios Using Continuously Evolving Tree of Simulations on Finite Memory Machines”, filed on May 22, 2025, under firm docket number 49224-25002A (ID5650.01), which is now United States Patent Number______, which claims the benefit of priority from U.S. Provisional Application No. 63/661,775, filed Jun. 19, 2024, titled “Speculative Evaluation of What-if Scenarios Using Continuously Evolving Tree of Simulations on Finite Memory Machines”.

### 4. TECHNICAL FIELD

This disclosure relates to cloning, and specifically digital twin technology.

### 5. RELATED ART

Some digital representations of physical objects require significant resources to make them accurate and reliable. Some digital representations rely on controllers, software, and sensors to generate predictions. Some representations process vast amounts of data to sustain them. The collection and storage of data require a significant amount of energy and cybersecurity to protect it. Further, when the amount of resources needed to reflect real-world physical systems is high, resource limitations can cause digital systems to fail.

### DESCRIPTION OF THE DRAWINGS

The system may be better understood with reference to the following drawings and description. The components in the figures are not necessarily to scale, emphasis instead being placed upon illustrating the principles of the invention. Moreover, in the figures, like-referenced numerals designate corresponding parts throughout the different views. The patent or application file also contains at least one drawing executed in color. Copies of this patent or patent application publication with color drawing(s) will be provided by the Office upon request and payment of the necessary fee.

FIG. 1 is a representation of [symbol] -tree simulation tree of simulated what-if scenarios or predicted states represented by simulated leaves.

FIG. 2 shows a representation of a clone tree execution synchronized to real time application of a digital twin.

FIG. 3 represents the rebasing of an originating [symbol] -tree at a level j into a rebased tree.

FIG. 4 shows an exemplary use case of a digital twin simulation generating simulated trees communicating a physical system state or a physical system states with an emulated physical twin.

FIGS. 5A-5C show voltage values from a physical twin and four leaf nodes, dt₀₀, dt₀₁, dt₁₀, and dt₁₁ of a simulation tree at (a) and absolute differences calculated on a log scale between a target system and the corresponding voltage predictions from leaf nodes dt₀₀, dt₀₁, dt₁₀, and dt₁₁ at (b).

FIG. 6 shows two runtime characteristics of a [symbol] -tree.

FIG. 7 shows the strong scaling of a [symbol] -tree that increases with the number of parallel processors shown by the number of threads through an open multi-processing architecture.

### DETAILED DESCRIPTION

Digital twin simulation systems and methods (also referred to as system(s) throughout this description) generate operational models of physical and/or virtual system(s) (also referred to as target system(s) and physical twin(s) throughout this description) from real-time data to predict, monitor, and/or improve the target systems' operation. Some systems communicate with the target system so that it may respond to one or more intervening events when they occur in real-time. The ability of the systems to provide real-time assessments and/or actionable data to the target system before those events occur to optimize the target system's performance and/or facilitate its dynamic adjustments that do not occur in conventional systems.

Some systems' large-scale execution of what-if conditions over time enable the prediction of future operating states in response to the intervention of foreseen and/or unforeseen events. The systems' analysis of expected and/or unexpected events and/or disruptions before they occur allow the target systems to dynamically respond efficiently, and in some applications, in real-time when they occur without the more significant computing resources conventional systems require. The systems' ability to integrate with and communicate with existing systems provide those target systems with just-in-time real-time analysis through seamless bi-directional data flows based on continuously evolving [symbol] -trees. This means that some systems provide up-to-the second analysis and interpretation of data (e.g., real-time accuracy), delivered immediately to the target system so that they may respond to events as they occur.

Through the evolving simulation clone trees, some systems create probabilistic simulated what-if scenarios under finite resource constraints. Improving target systems' operations under these constraints sometime translate into quantifiable grains over conventional systems. For example, some utility simulations may adjust parameters and/or reduce production time of target systems between about ten to about fifteen-percent. In an exemplary energy system, simulations may optimize load distribution based on predicted demand, predicted availability of energy sources, and/or the predicted operating physical system state of the infrastructure at various geographical locations to reduce energy transmission losses of the target system by about five to about ten-percent. These exemplary power grid systems reduce the mega-watt cost of power per hour. In some exemplary transportation systems, the systems' logistics may reroute deliveries based on real-time traffic data, predicted dynamic freight load measurements, and predicted fuel consumption to reduce high delivery times and high costs that represent underperforming states of the target systems by about five to about ten percent. Other applications include water treatment plant applications, nuclear power plant applications, military applications, security applications, mission critical applications, tactical applications, transportation network applications, virtual representations of other infrastructure, other applications, and other target systems, including those susceptible to disruptive states that may compromise safety, security, and/or economic stability. The exemplary quantitative improvements are derived from simulation-driven insights often based on simulated what-if analysis.

Some systems communicate with and simulate essential technologies. These systems model target systems in real-time and in some applications to process just-in-time data in response to receiving a physical system state of the target system. The systems inform the target systems of actionable measures to implement in response to one or multiple intervening events based on that physical system state enabling the target system to change state and avoid uncertainty. The actionable measures are scalable and enable dynamic adjustments by the target systems to these events before and/or when they occur.

In operation, the disclosed systems model the structure, context, and/or behavior of the target system. Some systems dynamically update with data from its target system, forecast future outcomes, and/or inform decisions. The bi-directional communication between the target system and its simulated counterpart improves the target system's operation. It does so by responding to different, and in some cases, intervening events continuously even in a resource-limited computing environments. Its configuration ensures that it is fast, scalable and/or capable of executing large-scale what-if analysis.

In some exemplary systems, simulation cloning comprises spawning a base simulation whose state spaces differ from its parent simulation (due to the intervening events) at runtime and concurrently advanced in simulation time to dynamically predict the impact of the intervening events through the simulation. In the context of a [symbol] -trees, an advancement at runtime means that a simulation cloning system can dynamically evolve, adapt, and/or optimize its processes while actively running or processing a current state of a target system. Instead of relying on pre-configured models, these systems integrate real-time data, refine predictions, and adjust behaviors in response to a current and/or an input operational state of the target system or information describing its environments. In short, it enables the self-improving system to be more accurate and efficient during its operation.

In the exemplary systems, when spawning occurs, spawned simulations form a tree of simulation clusters, where each of the simulations represents a distinct trajectory. It is distinct because of the deviation of the simulation clone's state space from its parent's state space. The deviation occurs as a result of the intervening events at the branching points of the [symbol] -trees (also referred to as k-trees).

In some applications, simulation cloning in discrete-event systems occurs faster than real-time because of the parallel structure of the systems' multicore architecture. The parallel system architecture achieves faster operation by dividing complex tasks into smaller sub-task simulations and processing them simultaneously across multiple processor cores. Unlike sequential systems that execute one task after another, the disclosed parallel [symbol] -tree system architecture currently process tasks that process inputs in shorter periods of time. The simultaneous output increases throughput, enabling more data to be processed, and more operations to be completed simultaneously rendering one or more responses or outcomes before a response or outcome is expected or occurs between physical systems. In some exemplary systems, the systems process the information faster than or at the same rate that they receive the data enabling the target systems to direct and/or control a process or system before it is needed, much like automatic pilots.

Some multi-core parallel processors interface memory systems that allow multiple memory access and multiple read and write cycles simultaneously, rather than sequentially. These systems enable parallel read and write operations, such as though interleaved memory banks in which memory is divided into several independent memory banks that are accessible simultaneously, for example. The systems processes input in parallel and in some applications, aggregate a plurality of outputs into one or more outputs.

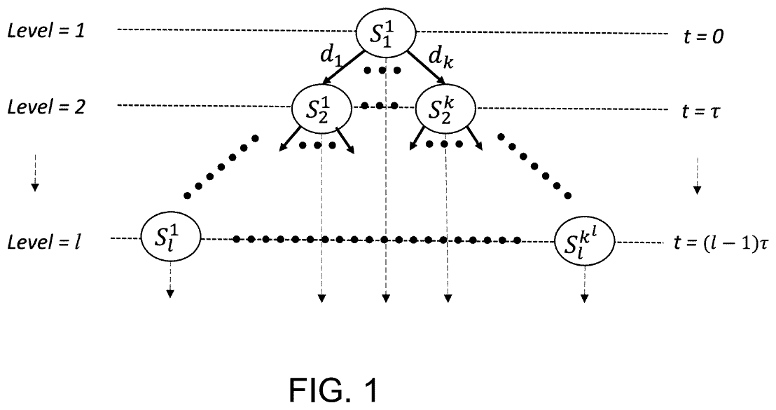

In FIG. 1 a simulation clone tree, also referred to as a [symbol] -tree, is constructed speculatively that informs its corresponding target system (aka, its physical twin) of the effects of k possible intervening events potentially occurring in the future at simulation time τ>0. The state of the simulation at actual time, that of a wall clock t known as physical time at time t=0 comprises a base simulation represented by

$${S}_{1}^{1} ,$$

where the subscript represents the processing level and the superscript represents the label of a child at a particular level.

The state of the simulation at physical time t=0, called the base simulation, is denoted by

$${S}_{1}^{1}$$

of the [symbol] -tree in FIG. 1. As we base simulation evolves by a simulation time τ increment, the simulation is subjected to k possible intervening events (e.g., analogous to simulated what-if-events and/or potential disruptions or a disruptive state), each of which may alter the trajectory of the base simulation. The modified or successive simulations rendered by the interventions are represented by k children nodes,

$${S}_{level \#}^{i} ,$$

(where i−1, 2, . . . , k) associated with the base simulation node

$${S}_{1}^{1} ,$$

In FIG. 1, the base simulation

$${S}_{1}^{1} .$$

continuously evolves by levels rendering k number of cloned children per level. The cloning is executed recursively after each cloned simulation evolves per t time increment, resulting in adjacent levels separated by simulation time intervals τ, which forms the [symbol] -tree.

Each of the k child nodes of the base simulation node, denoted by

$${S}_{2}^{1} … {S}_{2}^{k}$$

at all exemplary second level [symbol] for example, represent the simulation of a model trajectory affected by a disruptive event and/or other events at simulation time T (there are k possible such events being modeled). The resulting clone tree comprises a natural construct that represents the evolution of independent simulations that collectively capture the effects of k potential intervening events on the physical system after the passage of t simulation time. Similarly, at simulation time 2×τ at the second level, speculative evaluation of the next effects of k disruptive events at every k leaf simulation clone of the current simulation clone tree results in the introduction of k² additional simulation scenarios, such as those that would occur at the third level

$${S}_{3}^{1} … {S}_{3}^{{k}^{2}} .$$

Every node of the resulting [symbol] tree is an independently running simulation evolving synchronously and independently in a simulation time. Successive spawning and execution of the independent simulations result in an exponential growth of the simulation clone tree over simulation time, since at any level [symbol] , [symbol] clones are added to the tree.

In FIG. 1, the simulation clone at the root node, also called the base simulation, simulates the scenario that is unaffected by any intervening events. At the other end of the [symbol] -tree are the leaf nodes that capture the cascading effects of the events that occurred at each level after the passage of a simulation time t time period. The internal nodes of the simulation clone tree simulate the cascading effects caused by the various intervening events.

In FIG. 1, the simulation clone tree hosts simulations that evaluate the effects of combinations of cascading intervening events that vary in number, type, and/or times of occurrence across simulation paths (from a root to a leaf) in the [symbol] -tree. Rapid evaluations of these exponential number of simulations provide insight into what-if scenarios that may result in different outcomes of a target system. Those scenarios are expansive and, in some applications, include military grade simulations, tactical grade simulations, epidemiological simulations, and transportation simulations, and/or other simulations, for example.

The number of nodes in a simulation clone tree of degree K and depth [symbol] comprise

$${\sum }_{i = 0}^{ℓ} {k}^{i} = \frac{{k}^{ℓ} - 1}{k - 1} .$$

Each of these root-to-leaf paths represent an independent evolution of a target system subject to [symbol] intervening simulation times τ, 2τ, . . . , [symbol] t. Further, each simulation in a root-to-leaf path represents a simulation clone that differs from its parent trajectory due to the processing of an intervening event that created the simulation clone. Since the disclosed simulation clone nodes need not compute previous simulation states that its parent's node computed, the systems conserve computing resources, memory resources, and/or energy.

Because not all simulations share the same state-space occupied by a parent state, the dependency of the descendent children on the parent state space may be removed from their parent making independent simultaneous parallel execution of all the simulation clones possible. This dependency removal makes different modeling formalisms and their simulators to perform simulation cloning. This means that by eliminating or reducing the interdependence between different simulation models and their associated software (simulators), the systems can create identical or near identical copies of other distinct simulations without relying on a parent's state and subject them to separate, different, and/or mutually exclusive intervening events. Specifically, these types [symbol] -tree simulation enables a simulation application to speculatively simulate different trajectories of a base simulation through cascading incident events, both probable and/or un-probable, at τ simulation time up to the distant simulation time of [symbol] τ in parallel and independently.

The disclosed systems may comprise a virtual construct that executes in parallel with its target system that it models, which is also referred to as its physical twin. The systems may adjust execution and its clone trajectories based on inputs from its target counterpart. In this framework, the system continuously predicts future states of its physical twin by learning and synchronizing the characteristics that establish the current operating state of its physical twin so that it substantially mirrors, substantially duplicates, and/or substantially emulates its physical twin.

Because many different representations and/or models may substantially mirror, substantially duplicate, and/or substantially emulate a physical twin, many representative technologies may establish a baseline of the physical system state of a physical twin before an intervening event changes its state. In some applications, occurrences of events may be modeled using the current physical system state information received from the target system and/or received from an application-specific domain through the bidirectional communication. Real-world target systems characteristics that do not change a target system's operating state are also accounted for too, including those affected by non-occurrence events. In some simulations, a non-occurrence event refers to a scenario where an expected or planned event does not take place, and the analysis explores the potential consequences of that absence. Rather than focusing on what happens when something goes wrong due to a failure, the analysis of non-occurrence events examines what might occur if an action such as an action, response, and/or condition simply fails to happen—for example, a system doesn't activate, a signal isn't received, a sensor does not trigger, a communication does not occur, a military maneuver does not occur, or a backup process does not engage. The analysis of these conditions identifying vulnerabilities, assesses risk, and ensures that systems and/or processes are robust even when things don't go as planned. This also helps identify hidden vulnerabilities and assess how dependent a target system is on analyzing certain events occurring as planned. Evaluating non-occurrence events facilitates risk management and planning such as mission-critical planning, particularly in systems that support defense, economics, aerospace, and/or emergency responses, where the failure of something not happening can be just as impactful as something going wrong. Analyzing non-occurrence events helps decision-making systems prepare for unexpected outcomes and become more resilient.

Some systems are modeled with this information generated in the absence of an event to ensure that the simulations operate substantially like its physical twin. This modeling, analysis, emulations, etc. may account for the unpredictability the target system may experience. For example, a simulation model representing a physical twin may be affected by an event at time t, but then may not be affected by another event until time (t+y×τ) for some random integer represented by y between simulation levels 1 and [symbol] . Modeling combinations of such probabilistic occurrences and/or non-occurrences may result in a customization of a [symbol] -tree technology of future events.

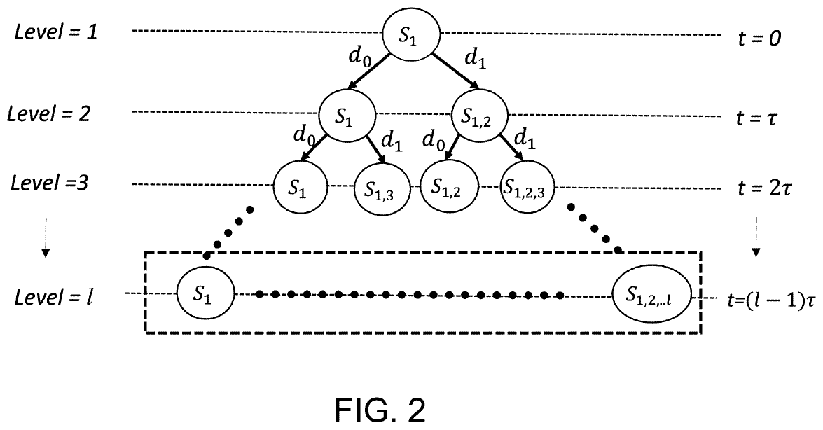

The inclusion of non-occurring events happens by including non-event instance of a parent at every level of a [symbol] -tree with k−1 state space-altering events. In operation, a non-event instance of a parent simulation advances by simulation time t without the occurrence of an intervening event. FIG. 2 represents this process with a binary (k=2) [symbol] -tree. In this [symbol] -tree with a k=2, events d₀ and d₁ occur, where the former refers to the non-event evolution of an operating state and the latter alters the operating state of the parent simulation. The events occur with a certain probability of the occurrence of an event, which results in the binary [symbol] -tree of depth [symbol] . The simulation clones whose state space is unaltered by the event d₀ are assigned the same label as its parent and the simulation clones that are altered by the event d₁ attach an [symbol] subscript to its parent designation. For example, S₁ at level [symbol] is not altered at any level and, as such, it retains the S₁ label at every level [symbol] whereas S_{1,2}, . . . , [symbol] is altered at each level and, hence, its subscripts at level [symbol] contain all the levels at which the state-space was altered before reaching level [symbol] . Essentially, the [symbol] -tree of depth [symbol] computes [symbol] leaf simulation clones identified by events, with each simulation trajectory created from a unique combination of k−1 events and non-events at each level. In FIG. 2, the systems include the occurrence of an intervening event, non-occurrence events, and different combinations of cascading event occurrences. These influences are represented by the modified simulation clone tree.

Some [symbol] -tree simulation cloning frameworks can be further modified and adapted for other digital twin applications. A modification may be made by further modeling. A model may establish δ as the response time within which a target system requires information to be informed by the system. A model may meet this requirement by establishing that the product of the simulation level [symbol] and incremental simulation steps τ be generated in less time than δ as expressed by [symbol] ×τ≤δ. By this constraint, a [symbol] -tree of depth [symbol] captures all possible simulations that are needed to inform the target system subjected to k intervening events within the δ response time period.

In this exemplary model, the resulting [symbol] -tree has [symbol] root-to-leaf paths, each representing a unique scenario. It may be further expressed by letting τᵥ represent the computational time required to compute all [symbol] root-to-leaf paths of the simulation trajectories. Since all the simulation clones in the [symbol] -tree execute independently of each other, the compute time may be reduced from τᵥ to

$$\frac{{τ}_{v}}{{k}^{ℓ - 1}}$$

when generated by p= [symbol] parallel processors. Parallelism accelerates the models. P=q× [symbol] processors may compute [symbol] simulation scenarios simultaneously, where each running parallel process reduces the time required to deliver data to the target system and/or for the target system to process the data and those recommendations. Unlike generic simulation clone trees, the disclosed trees only need simulation at the leaves of the [symbol] -tree to be advanced at each t simulation time.

Construction of tree of simulations is usually computationally expensive, and its growth in simulation time is usually restricted by limited computing resources, especially memory resources. But the disclosed [symbol] -tree is not as restricted. To compute future state spaces using the disclosed [symbol] -tree simulation cloning models, the systems' resources are reclaimed. Reclamations occur by releasing the [symbol] -tree simulation nodes that become stale and/or are less relevant after the passage of periods of time. A [symbol] -tree node is considered stale when the data and/or state it represents is outdated, changes, or no longer reflects the current operating conditions and/or possible operating conditions of the target system it is simulating. This may occur when parameters are updated, a new input or new inputs are processed, and/or when new models have not propagated through the tree rendering a new root node, for example. As a result, those nodes may hold old values or results that do not align with the operating state of the target system. To maintain the integrity of the simulation system and conserve resources, these nodes are pruned and the computer resources maintaining them reclaimed. This may occur after TR periods of time. τ_{R} relates to the virtual timeline governing the evolution of the systems. τ_{R} is the computational time in which the target system functions and evolves.

For example, after a first τ_{R} real time period, the trajectory of a target system will correspond to one of the k−1 children of the root simulation node. At this point, the cloning tree will retain a single instance of the simulation that corresponds to the actual state of the target system and its descendants at time TR. Correspondence may be identified by comparing the current operating state of the target system to the simulation instances and selecting the single instance based on a comparison to predetermined criteria. To ensure that the [symbol] -tree remains synchronized to the current conditions of the target system and that there are sufficient computing resources to support extended simulations, the system prunes the other simulation instances corresponding to the remaining k−1 children of the originating root, their descendants, and the originating root itself. As those nodes are released, the child that becomes the root corresponds to the actual state of the target system are rebased. That is child node most closely reflecting the current conditions of the actual state of the target system based on predetermined criterion becomes the new root.

In more detail, the system selects the next root node by comparing the real-time operational state of the target system with the states of the simulation instances (child nodes) generated from the previous root node. The predetermined criterion, which could be a set of sensor readings, performance metrics, relevant data, or other comparison thresholds identifies the simulation instance that most accurately reflects the current state of the target system. This selected simulation instance becomes the new root node for the next simulation tree. To maintain computational efficiency and synchronization, all other simulation instances (the remaining child nodes of the previous root, their descendants, and the previous root itself) that include those that are not aligned with the current operational state of the target system (e.g., that in some applications are labeled underperforming or underperforming states) are pruned, effectively discarding them. This pruning ensures that the rebased simulation tree focuses on the most relevant path, aligning with the actual trajectory of the target system. Further, the selection, pruning, and spawning may be repeated during the operational life of the target system.

In short, the systems' rebasing process removes non-actionable outcomes by releasing the remaining k−1 children and their associated memory (such as in shared memory systems) with the computing resources that maintain them making them available for reuse such as for spawning new simulation nodes. By periodically releasing nodes and reclaiming the resources that maintain them, the systems prevent leaks such as memory leaks, for example, which occur when memory is allocated but never freed, leading to its depletion. The process of releasing and reallocating computing resources, such as memory and processor cores ensure that the systems dynamically respond to the target systems' needs as the system continues to forecast future outcomes in response to different conditions, disruptive events and/or other events.

In the disclosed systems, the number of removed simulation clones ( [symbol] ) equals the number of newly spawned simulation clones. In alternate systems, the number removed simulation clones is equal to and/or is greater than the number of newly spawned simulation clones. A release and reallocation creates a new [symbol] -tree of size

$$\frac{{k}^{ℓ - 1}}{k - 1} .$$

When k and [symbol] levels are generated, the original [symbol] -tree before rebasing is supported by its computer system's resources. Pruning at times less than or equal to TR times generates a rebased [symbol] -tree that uses no more resources than the resources that generated the original [symbol] -tree before rebasing.

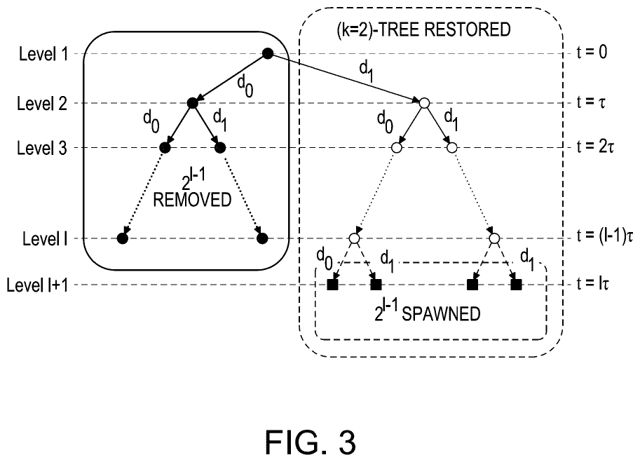

An example of aa [symbol] -tree simulation cloning framework that continuously reuses system resources with a k=2 is shown in FIG. 3. To account for the overhead of resource recycling in a real implementation, the exemplary [symbol] -tree ensures

$$( \frac{{τ}_{v}}{{k}^{ℓ - 1}} + {τ}_{recycle} < {τ}_{R}$$

with p= [symbol] , where τ_{recycle} represents the computational time required for resource recycling. This means that the computational time required to simulate the exemplary system within the simulation time is less than or equal to the time it takes for the target system to function and evolve. In short, the computational time, t, required to construct a [symbol] -tree of depth [symbol] is less than or equal to the time in which the target system evolves (t≤τ_{R}) when a [symbol] -tree does not exist, which maintains synchronization. The computational time, measured in actual time or real-world time, represents the time required to advance the virtual system by a simulation time.

In practice, the time constraint may be increased or decreased through parallelization (p˜O(k [symbol] )), which ensures that future states of the systems are computed before the corresponding real-world time of the target system's execution lapses. This ensures that the target system is informed. Functionally, the computational time for a simulation clone tree to advance to 1×τ need not be less than the target system's operational and evolutionary timeline once the [symbol] -tree is constructed. Once built, the [symbol] -tree needs only to advance in t simulation time. Further some of the prior computed state spaces can be retained during the resource recycling and reallocation process and construction of the [symbol] -tree can be incrementally built over several system synchronization time periods provided τ<τ_{R}.

An exemplary tree-based power simulation use case executed a probabilistic model to assess the cascading failure of transformers in the power grid experiencing geomagnetic disturbances caused by solar storms. The probability of failure was computed as a function of a solar storm's intensity, the transformers' physical properties, the geographical location of the transformers, and the flow of electric power. Solar storms result in geomagnetically induced currents (GICs) that enter the power grid through transformers and cause severe impacts on the components of the grid. GICs are determined by solving a DC network of the form expressed in equation 1.

$$I = GV \qquad ( 1 )$$

In equation 1, G comprises a square matrix of conductance values that include substation (or bus) grounding resistance values and winding resistance values of transformers in the system. The vector V contains entries for the bus DC voltages, and Norton equivalent currents are represented by I. To compute the induced voltage, the solar storm electric field is integrated over the length of the transmission line as expressed in equation 2.

$$V = {E}_{x} {L}_{x} + {E}_{y} {L}_{y} , \qquad ( 2 )$$

In equation 2, Ex=E cos (θ) comprises the electric field in the east-west direction (V/km), E_{y}=E sin (θ) comprises the electric field in north-south direction (V/km). Lₓ comprises the eastward distance (km). L_{y} comprises the northward distance (km), θ comprises the direction of the electric field E. A substantially constant or uniform electric field, independent of the transmission line's path was used.

The exemplary use analyzed an IEEE 118 bus system subject to a notional solar storm. An IEEE 118-bus system comprises 19 generator transformers, 35 synchronous condensers, 177 lines, 9 step transformers, and 91 loads. The voltage based rating for the majority of buses is 138 kV. The computation of GICs typically processes specific data, including the configuration of the transformers, their physical condition, their physical locations, the transformer windings' resistances, and the ground resistances of buses. In the exemplary use case, assumptions established that the configuration of the transformers are not provided in the data, and that the transmission to distribution transformer has a typical delta-wye configuration. The transmission system transformers that include transformers that step up voltages and/or that step down voltages were modeled as wye-wye connected. Because IEEE data do not model generator transformers (GT), the ratings of the GTs were established as those used in conventional power grid simulations. In this use case, transformers are devices that stepped up voltages and/or stepped down voltages via electromagnetic induction and GTs are the power transformers that connect a power generator to the grid. GTs are usually used for efficient long-distance voltage transmissions. The GTs generally have a delta-wye-to-ground connected configuration with the delta connection on the generator side. The exemplary use case assigned the geographic coordinates to the 118 buses of an exemplary test system. The coordinates were restricted to the continental United States, with no two buses having a greater distance than about 500 km or about 310 miles between them.

The exemplary use case established the transformer winding resistances generally range from a few milli-Ohms to several Ohms, but generally on the lower end of the scale. The winding resistances were assigned low resistance values based on the voltage ratings of the transformers, which is consistent with IEEE Standards. The exemplary use case recognized that substation grounding resistance varies with several factors, including the size of the buses (representative of the base voltage rating of the buses), for example. For that reason for higher-rating buses, the ground resistance was established to be about 0.1Ω, and those with lower voltage ratings assigned a relatively higher ground resistance of about 0.5Ω, which is consistent with IEEE standards. A notional solar storm with an E equal to about a 1V/km field with an angle of about θ=90 degrees was analyzed by the exemplary use case.

A power simulation emulating a target system modeled the physical assets of the power grid in the use case through a random number generator that modeled random disruptive events by its output. In this exemplary emulation, a random value that was greater than or equal to a predetermined value, disabled a high power transformer. When the random value was less than that predetermined value, the emulated target system did not change. In this emulation, the random numbers modeled the random nature of some disruptive events that would affect the physical asset that comprise the physical power grid known as the target system.

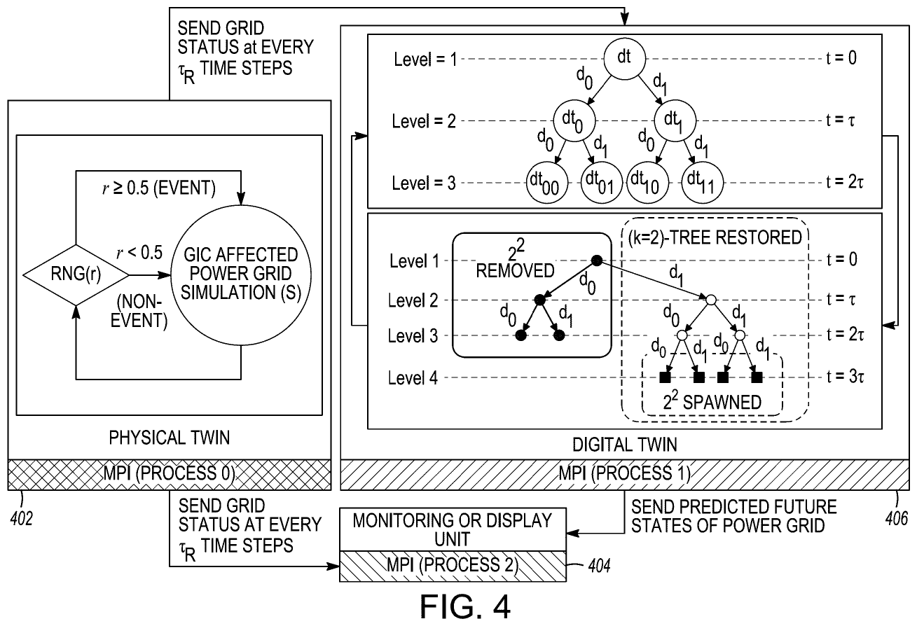

In response to a random number event, the emulated target system's time advanced. When the failures occurred, a transformer characterized as having a high probability of failure was removed and identified to the system (e.g., the digital twin simulation), before a load flow. Similarly, when failures did not occur, the operating state of the emulating target system 402 was communicated to the system. In this exemplary use case, state-space information and the current levels were communicated to a monitoring unit 404 of FIG. 4 via a communicating system or communication circuitry.

In this exemplary use case, the digital twin simulations system 406 performed speculative computations through probabilistic events to generate a simulation clone tree as shown in FIG. 4. Each leaf of the simulation clone spawned two simulation clones at each t simulation time steps. The first simulation clone was the result of a non-event instance. The second simulation clone simulated a transformer failure event that deactivated a transformer having a high probability of failure. A clone tree of depth 1=2 was created. At every t simulation time advancement, only the leaf simulation clones were generated independently and in parallel delivering a linear speedup.

The digital twin simulation system 406 communicated with the emulating target system 402. Based on that communication, the clone trees rebased its roots, spawned new leaf simulations, released and reallocated computer resources that supported pruned clones, and advanced the leaf simulation clones by t units of simulation time. In this use case, transformers having a probability rate of failure were removed when the random value exceeded or was equal to the predetermined value. Further, each leaf simulation clone spawned two children simulation clones—one that represented a non-occurrence event and another that represented a failure event. Multiple branches (k>2) of the clone tree were supported, where scenarios of failure events of other k−1 transformers occurred speculatively. The clone trees were transitioned to scenario that executed rebasing and communicated with the emulating target system 402. After spawning new leaf simulation clones, the systems advanced by t units in simulation time. In this use case, digital twin simulation system 406 advanced the simulations in simulation time by 1×τ period of time ahead of the emulating target system 402. The state information of the leaf simulation clones was communicated to the monitoring unit 404 through transceivers and a bidirectional buses. In this use case, at simulation time τ=1.0 steps voltage magnitude values of all the buses were communicated by the emulating target system 402 and digital twin simulation system 406 to the monitoring unit 404 through communication circuitry.

The monitoring unit 404 observed and tracked the emulating target system 401 and the digital twin simulation system 406 by collecting data from both. The current state of the system is sent by the emulating target system 402 and the future states of the physical asset (referred to as physical system state) at t×1 based on the [symbol] -trees or clone trees by the digital twin 406. The digital twin 406 sent state information from its simulation leaf nodes that encompassed combinations of non-disruptive and disruptive events over τ+1 time in the future. Because a simulation clone tree of k=2 and 1=2 was generated in this use case, four possible states at a future simulation time τ+2 were transmitted to the monitoring unit 404. As shown via FIGS. 3 and 4, dt₀₀, dt₀₁, dt₁₀, and dt₁₁ comprise four leaf nodes. Leaf node dt₀₀ represents the simulation scenario that holds the future state where no failure event occurs either at τ+τ or τ+2τ time instances. Leaf node dt₁₁ represents the simulation scenario that holds the future simulation state of cascading failures where failure events occur both at τ+τ and τ+2τ time instances. In the simulation of dt₀₁ and dt₁₀ leaf nodes, failure event occurred only once with each scenario differing by the order in which the failures occur. During simulation runs that did not analyze power load or generation changes at each time step, non-simulation events were assigned to the nodes that were the same state values as the node's parents. In those simulation runs that do not consider power load or generation changes at every time step, the state space of leaf nodes dt₀₁ and dt₁₀ are the same and the state values communicated from the emulating target system 402 have the same state as the base leaf node dt₀₀ of the simulation tree communicated by the digital twin 406.

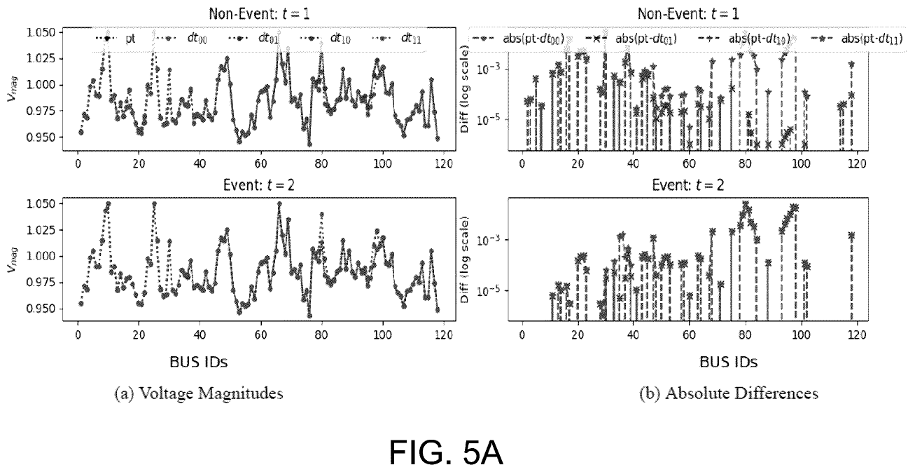

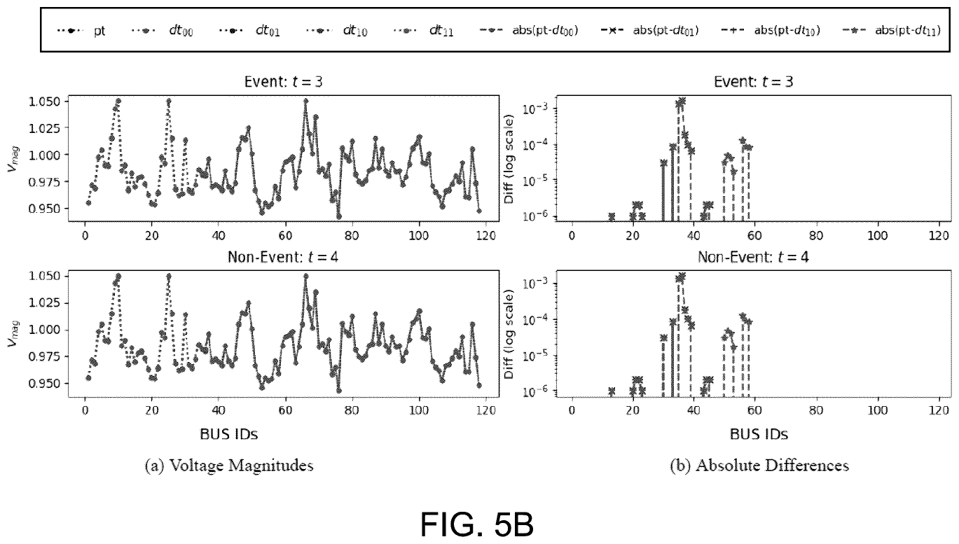

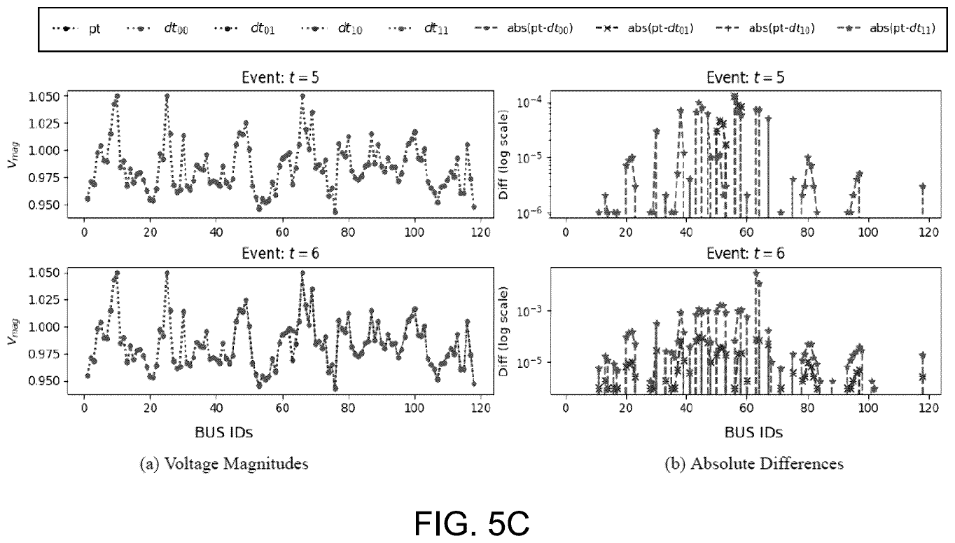

The use case was executed on a server hosting eight cores (sixteen threads) of an Intel(R) Xeon(R) W-2245 CPU @3.90 GHz. The server included a system memory of 128 GB and executed the [symbol] -tree simulation cloning framework disclosed in U.S. Application titled “Speculative Evaluation of What-if Scenarios Using Continuously Evolving Tree of Simulations on Finite Memory Machines”, under firm docket number 49224-25002A (ID5650.01), that was filed on the same day as this disclosure and is incorporated herein by reference. FIG. 5A-5C show the voltage values generated by the emulating target system 402 and the voltages predicted by the leaf nodes of the simulation clone tree from the first six-time steps collected at the monitoring unit 404 and stored in memory. The label pt, or physical twin, refers to the emulating target system 402, and dt₀₀, dt₀₁, dt₁₀ and dt₁₁ refers to leaf nodes of the simulation clone tree of depth=3 generated by the digital twin 406. Each subplot in (a) show the event occurrence and non-event-occurrence of a failure event of the emulating target system 402 in FIGS. 5A-5C. As shown, no failure events occurred at t=1, which was followed by a failure event at t=2. Another failure event occurred at t=3, which was followed by no failure event at t=4. Each subplot in (b) shows absolute difference of voltage magnitudes generated by the emulating target system 402 against those predicted by the digital twin 406. The line plot of the emulating target system 401 shows the voltage magnitudes at a current time (t). Here, leaf dt₀₀ of the simulation clone tree comprises a future voltage magnitude at (t+2) that results from consecutive non-occurrence events at (t+1) and (t+2). Since no load or generation power changes occurred at each step in this use case, the voltage magnitude occurring during the non-occurrence events did not change. Hence, the line plot of the target system and the leaf node dt₀₀ of the simulation clone tree overlap in (a) resulting in no difference in the voltage magnitude between the emulating target system and the simulation clone tree at that node in (b) in FIGS. 5A-5C. The voltages represented by leaf nodes dt₀₁ and dt₁₀ of the simulation clone tree are also the same because non-occurrence events did not change the state values of the systems. The overlap shown in (a) coincides with no voltage difference as shown in (b) in FIGS. 5A-5C.

The line plot at leaf node dt₁₁ simulates the effect of cascading failure events at (t+1) and (t+2). The sub-plot of the emulating target system or physical twin, pt, follows the same trajectory predicted by leaf node dt₁₁ of the simulation clone at t=4 when no failure event occurred, which verifies in part that the simulation clone trees are operating as a digital twin simulation. This is further shown through the voltage predictions of leaf nodes dt₀₁ and dt₁₀ during the non-occurrence event at t=1, which is followed by the emulating target system 401 or physical twin 406 pt failure event at t=2. Even though leaf nodes dt₀₁ and dt₁₀ are predictions at t+2, the occurrence of a non-occurrence event in their trajectory enables the leaves to capture voltage magnitude after a single failure event.

Since the voltage magnitudes are represented in units, the differences in the voltage magnitudes between the emulating target system 401, pt, and the emulating digital twin's predicted values are not entirely visible in (a) for the entire timeline, the differences are shown in (b), which visualizes how the systems are different at t=3, t=4 and t=5 via FIGS. 5A-5C.

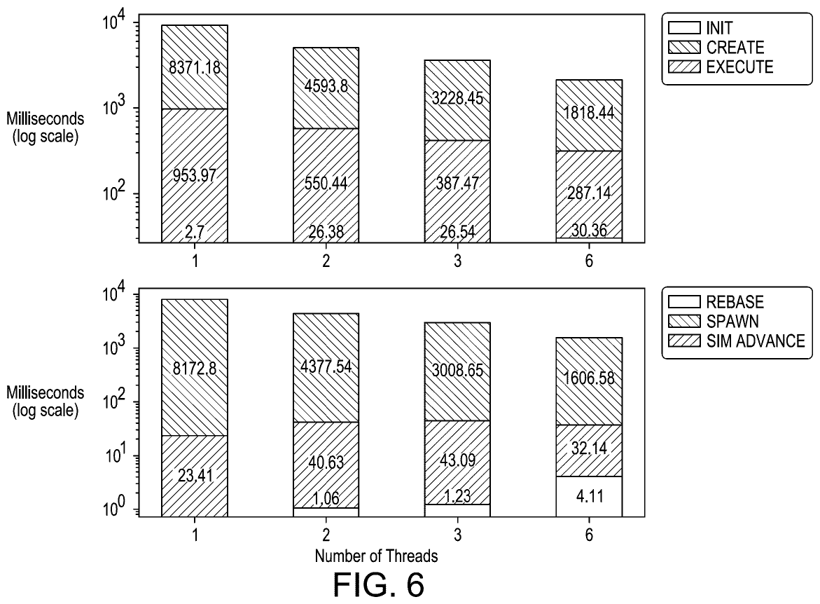

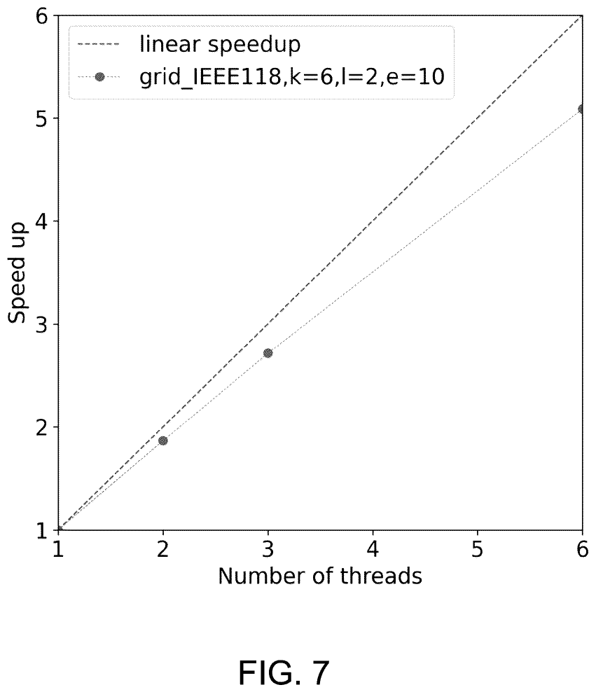

In the exemplary use case, the leaf nodes of the simulation clone tree were run in parallel using an open multi-processing application programing interface (MPI) as shown through FIGS. 4 and 6. The system having a k=6 and an l=2 was executed through increments of 10 milliseconds. The bar charts shows the time differences staring with the initialization of the base simulation (Init), the construction of the initial simulation clone tree (Create), and execution of the simulation clone tree with a rebasing (Execute). The vertical axis or y-axis is in a log-scale. As shown, the execution of the simulation clone tree and rebasing consumed the majority of the runtime as shown in the upper graph of FIG. 6. In the lower graph of FIG. 6, the execution of the simulation clone tree with the rebasing was separated into subtasks, namely, clone tree rebasing time (Rebase), spawning of new clones (Spawn), and advancing simulation step of simulation clone tree leaf simulations (Sim advance). As shown, the simulation step of simulation clone tree leaf simulations consumed two orders of magnitude more time than Rebase and Spawn processes combined. When the simulation step of simulation clone tree leaf simulations were executed in parallel through an open multi-processing application program interface (MPI), the emulating target system 402 against and the digital twin 406 speed increased. FIG. 7 shows the strong scaling result by showing a linear speedup, meaning the program's execution time decreased proportionally to the fewer number of processors used. In the power grid exemplary use case, six processors were used for scaling and two processors were used to emulate the target system or physical twin.

The disclosed systems precompute different possible trajectories of a target system before their occurrence. The system's process of pruning stale and/or non-relevant trajectories to reclaim computing resources periodically occurred during synchronization periods with the target system in some applications. The practice of pruning stale and/or non-relevant trajectories and re-using previously computed states to conserve computer resources and making them adaptable to support changing operating environments, is not always foreseeable to conventional systems and increases throughput in the disclosed system. The disclosed practices overcame the challenge of performing simulated what-if analysis under the constraints of limited computational resources. The systems further benefit from parallel processing as the number of threads (e.g., representing execution by separate processors operating in parallel) increased as shown in FIG. 7.

The disclosed systems are capable of informing a target system continuously even when restricted by limited computing resources. The disclosed systems are parallel and, hence, highly scalable and may be customized to respond efficiently when operating under time constraints. The system have utility working with any systems including power grids such as those susceptible to geo-magnetically induced currents as discussed in the exemplary use case. The disclosed systems may operate with local unitary memory in parallel read-write cycles or local and/or remote distributed-memory in parallel to further reduce latency.

In this disclosure, when functions, steps, etc. are “responsive to” or occur “in response to” another function or step, etc., the functions or steps necessarily occur as a result of another function or step, etc. A device or process that is responsive to another requires more than an action (i.e., the process and/or device's response to) merely follow another action. The term “substantially” or “about” encompasses a range that is largely in some instances, but not necessarily wholly, that which is specified. It encompasses all but a significant amount, such as what is specified or within five to fifteen percent. In other words, the terms “substantially” or “about” means equal to any value within that range or a range within or about five to fifteen percent. Forms of the term “cascade” and the term itself refer to an arrangement of two or more components such that the output of one component is the direct input of the next component (e.g., in a series connection). The term “unitary” refers to an indivisible entity, oneness, and singularity. It refers to a single indivisible entity or component.

This disclosure describes design and analysis of a novel, speculative tree-based framework for efficient executions of simulation cloning that may be restricted by finite memory resources and other computing hardware limitations. The performance of an exemplary implementation, referred to as a [symbol] -tree-programming-framework is described in in the context of an exemplary power grid control. The simulations relied on an exemplary shared memory computing host equipped with multi-core CPUs and/or GPU accelerators that executed the processes stored in a non-transitory machine-readable medium such as a non-transitory media, computer readable medium or a memory and executed by the systems disclosed in United States Patent Application “Speculative Evaluation of What-if Scenarios Using Continuously Evolving Tree of Simulations on Finite Memory Machines,” that was incorporated by reference herein in its entirety. The [symbol] -tree-programming-framework used comprises a simulation type-agnostic programming platform and supports simulations of all types, viz., time-stepped, discrete-event, hybrid, agent-based, and others. Additionally, the design of the [symbol] -tree-programming-framework may be used with any third-party simulator. This [symbol] -tree-programming-framework is adopted to function as a digital twin. To accommodate this function [symbol] -tree programming framework is altered to support non-event simulation clones.

The disclosed rebasing enables the systems of simulation clones to execute without restriction even within finite incremental memory sizes via a memory-aware and/or as-long-as-needed execution strategies. The [symbol] -tree-programming-framework has been used in distributed memory parallel settings, for at-scale simulation cloning of physical conditions and physical models, for example, with applications directed to digital twins for various infrastructure systems.

Further, the various elements and system components, and process steps described in each of the many systems and processes described herein is regarded as divisible with regard to the individual elements described, rather than inseparable as a whole. In other words, alternate systems encompass any variation and combinations of elements, components, and process steps described herein and may be made, used, or executed without the various elements described (e.g., they may operate in the absence of) including some and all of those disclosed in the prior art but not expressed in the disclosure herein. Thus, some systems do not include those disclosed in the prior art including those not described herein and thus are described as not being part of those systems and/or components and thus rendering alternative systems that may be claimed as systems and/or methods excluding those elements and/or steps.

Other systems, methods, features, and advantages will be, or will become, apparent to one with skill in the art upon examination of the figures and detailed description. It is intended that all such additional systems, methods, features, and advantages be included within this description, be within the scope of the disclosure, and be protected by the following claims.

The invention claimed is:

1. A system comprising:
communication circuitry that receives updates of a state of a physical system, the communication circuitry updates at a simulation time interval τ;
a processor that operates a digital twin of the physical system by
obtaining an update of the physical system's state,
simulating a tree of what-if scenarios that represent what can happen during a base simulation of the physical system starting from its updated state, wherein the tree comprises l levels and each level j comprises k leaf nodes, where 1≤j≤l, where leaf node i=1 corresponds to a non-event rendering a physical system state remains unchanged and the (k−1) remaining leaf nodes i correspond to events that disrupt the physical system state, where 2≤i≤k,
storing the simulated tree in a memory,
(i) obtaining a next update of the physical system's state and comparing it with a plurality of predicted states corresponding to the k leaf nodes of a second level j=2 of the simulated tree,
(ii) selecting a leaf node of the second level j=2 that corresponds to the predicted state that is substantially the same physical system state associated with a current update, and rebasing the tree at a selected leaf node,
(iii) removing from the memory the simulated what-if scenarios of the tree that are not a part of a based tree, and allocating to a memory space that serves the simulated what-if scenarios of the tree that are part of the rebased tree, and
(iv) executing a simulation of a plurality of leaves of the rebased tree, and storing the plurality of simulated leaves in the memory, and
iterating a plurality of operations (i)-(iv) for the rebased tree; and
a monitoring unit programmed to
monitor a plurality of predicted states of the physical system corresponding to the leaves of an instance of the tree currently stored in memory,
determine whether one or more of a plurality of predicted states correspond to a plurality of underperforming states of the physical system, and
communicate with the physical system via the communication circuitry by identifying a plurality of disruptive states to the physical system before a disruptive state occurs within a time period of τ≤(l−1)τ.

2. The system of claim 1, where
the physical system comprises a power grid that has N transformers,
the base simulation corresponds to a simulation of the power grid, and
the what-if scenarios correspond to a plurality of simulating instances of the power grid from which a respective one of a plurality of (k−1) transformers is removed from the power grid, where (k−1)<N.

3. The system of claim 1, where the physical system comprises one of
a nuclear power plant,
a water treatment plant, or
a transportation network.

4. The system of claim 1, wherein the physical system comprises a physical twin that models the physical system.

5. The system of claim 1, where the processor executes a [symbol] -tree simulation

6. The system of claim 1, where the processor executes a rebase of the tree when a plurality of parameters that reflects an operating state of the physical system updates.

7. The system of claim 1, where the processor executes a rebase of the tree when the physical system receives a new input.

8. The system of claim 1, where the processor executes a rebase of the tree when a new simulation based on a root node that was previously a child node.

9. The system of claim 1, where the processor executes a tree simulation by executing a plurality of successive simulations in response to a plurality of intervening events.

10. The system of claim 1, where the processor rebases a portion of a tree by a cloning of a portion of a state space of a parent node that shares state and data with the selected lead node

11. The system of claim 1, where the processor executes a speculative computing and a rebasing.

12. The system of claim 1, where
a base simulation corresponds to simulating a power grid that comprises N transformers and further comprises a plurality of generators, and
the what-if scenarios correspond to simulating instances of the power grid from which a respective one of a plurality of k transformers having a t probability of failure is removed from the tree.

13. The system of claim 1, where
a base simulation corresponds to simulating a power grid that has N transformers and has a plurality of generators, and
the what-if scenarios correspond to simulating instances of the power grid from which a respective one of a plurality of k transformers having a highest probability of failure is removed from the rebase tree where k<N.

14. A system comprising:
a communication circuitry that receives updates describing a state of a physical system;
a processor in communication with a digital twin of the physical system by:
obtaining an update of an operating state of the physical system;
simulating a tree of a plurality of what-if scenarios from a base operating state of the physical system starting from a current operating state, where the tree comprises l levels and each level j comprises k leaf nodes, where 1≤j≤l, where a leaf node i=1 corresponds to a non-event rendering a physical system state remains unchanged and a plurality of (k−1) remaining leaf nodes i correspond to a plurality of events that change the current operating state of the physical system state, where 2≤i≤k;
storing a simulated tree in a memory;
(i) obtaining an update of the state of physical system and comparing it with a plurality of predicted states corresponding to the k leaf nodes of a second level j=2 of the simulated tree;
(ii) selecting a leaf node of the second level j=2 of the simulated tree that corresponds to a predicted state that comprises a second current state of physical system state, and rebasing the tree at a selected leaf node,
(iii) removing from the memory a selected plurality of simulated what-if scenarios of the tree that are not a part of a based tree, and reallocating a memory space that serves the simulated what-if scenarios of the tree that are part of the rebased tree, and
(iv) executing a simulation of a plurality of leaves of the rebased tree, and storing the plurality of simulated leaves in the memory, and
iterating a plurality of operations (i)-(iv) for the rebased tree; and
a monitoring unit programmed to:
monitor a plurality of predicted states of the physical system corresponding to the leaves of an instance of the tree stored in the memory;
determine whether one or more of a plurality of predicted states correspond to a plurality of underperforming states of the physical system; and
communicate with the physical system through the communication circuitry by identifying a plurality of potential states to the physical system before a potential underperforming state occurs.

15. The system of claim 14, where
the physical system comprises a power grid of transformers,
a base simulation corresponds to a simulation of the power grid, and
the plurality of what-if scenarios correspond to a plurality of simulating instances of the power grid from which a respective one of a plurality transformers is removed from the power grid.

16. The system of claim 14, where the physical system comprises one of a nuclear reactor, a water treatment plant, or a transportation network.

17. The system of claim 14, wherein the physical system comprises a physical twin that models the physical system.

18. The system of claim 14, where the processor executes a [symbol] -tree simulation

19. The system of claim 14, where the processor executes a rebase of the tree when a plurality of parameters that reflect an operating state of the physical system updates.

20. The system of claim 14, where the processor executes a rebase of the tree when the physical system receives a new input.

21. The system of claim 14, where the processor executes a tree simulation by executing a plurality of successive simulations in response to a plurality of intervening events.
